(19) United States
(12) Patent Application Publication
(10) Pub. No.: US 2011/0162686 A1
(43) Pub. Date: Jul. 7, 2011

(54) METHOD FOR INSTALLING PHOTOVOLTAIC MODULES AND A PHOTOVOLTAIC ARRAY

(75) Inventors: Andreas Heidelberg, Dresden (DE); Harald Bloess, Erfurt (DE)

(73) Assignee: MASDAR PV GMBH, Ichtershausen (DE)

(21) Appl. No.: 12/984,659

(22) Filed: Jan. 5, 2011

(30) Foreign Application Priority Data
Jan. 6, 2010 (DE) 10 2010 004 127.0

(51) Int. Cl. H01L 31/042; H01L 31/18; B23P 11/00

(52) U.S. Cl. 136/244; 29/890.033; 29/428

(57) ABSTRACT

A method of installing a photovoltaic module includes providing a stationary substructure configured as a supporting and affixing structure and affixing the photovoltaic module to the substructure with an adhesive bond. A photovoltaic array includes a stationary substructure configured as a supporting and affixing structure and at least one photovoltaic module affixed to the substructure by an adhesive bond.

### CROSS REFERENCE TO RELATED APPLICATIONS

This application claims priority to German Patent Application No. DE 10 2010 004 127.0, filed on Jan. 6, 2010, which is hereby incorporated by reference herein in its entirety.

### FIELD

The invention relates to a method for installing photovoltaic modules and to a photovoltaic array.

### BACKGROUND

German utility model DE 20 2008 013 755 U1 describes a conventional photovoltaic array, in which a photovoltaic module is affixed to a stabilizing structure by means of an adhesive bond. As a result, a flat reinforcing and stabilizing element is created for a photovoltaic module, especially for a frameless glass-glass laminate, whereby, instead of several individual profiles or a reinforcing or stabilizing element consisting of several parts, a flat, one-piece reinforcing and stabilizing element is affixed to the bottom of the module. The photovoltaic module produced in this manner is subsequently mounted on a stationary substructure located, for instance, on a roof.

A drawback of such a photovoltaic array and of the method for installing it is that, aside from the substructure, there is also a need for a stabilizing structure, which makes this solution laborious in terms of its production engineering and installation.

### SUMMARY

In an embodiment, the present invention provides a method of installing a photovoltaic module including providing a stationary substructure configured as a supporting and affixing structure and affixing the photovoltaic module to the substructure by an adhesive bond. In another embodiment, the present inventin provides a photovoltaic array including a stationary substructure configured as a supporting and affixing structure and at least one photovoltaic module affixed to the substructure by an adhesive bond.

### BRIEF DESCRIPTION OF THE DRAWINGS

Embodiments of the present invention are described below with reference to the drawings, in which:

FIG. 1 shows a schematic depiction of an installed photovoltaic array;

FIG. 2 shows a first installation step for a photovoltaic module of the photovoltaic array of FIG. 1;

FIG. 3 shows a second installation step for a photovoltaic module of the photovoltaic array of FIG. 1;

FIG. 4 shows a plan view of the bottom of a photovoltaic module.

### DETAILED DESCRIPTION

An aspect of the present invention is related to creating a method for installing photovoltaic modules as well as a photovoltaic array with which simple production and installation are possible with minimal production engineering work and low manufacturing and installation costs.

In an embodiment of the method for installing or affixing photovoltaic modules to a substructure, the photovoltaic modules are affixed to a stationary substructure configured as a supporting and affixing structure by means of an adhesive bond. From a production engineering standpoint, the photovoltaic module can be easily configured as a glass-glass laminate. In contrast to the state of the art, which involves a stabilizing structure affixed to the photovoltaic modules, it was recognized a stable photovoltaic array without such a stabilizing structure can be achieved in that, during the installation, the photovoltaic modules are affixed essentially directly to a substructure configured as a supporting and affixing structure by means of an adhesive bond. As a result, there is no need for any additional stabilizing structure associated with the modules, so that the production engineering work is minimized and the costs for the manufacture, transportation and installation are reduced.

It may be advantageous to affix the photovoltaic modules to the substructure by means of double-faced adhesive tape, for instance, adhesive strips. Consequently, the modules can be installed on the substructure easily and quickly. In terms of production engineering, the double-faced adhesive tape can be easily applied, for instance, automatically, to the bottom of the photovoltaic modules while they are being produced. With the use of the double-faced adhesive tape, the adhesive tape can be affixed to the module as well as to the substructure. The one-side fixation to the substructure allows the adhesive surface to be protected by the peel-off backing of the adhesive tape until immediately before the installation of the photovoltaic module.

In order to position the photovoltaic modules during installation, that is to say, before and during the creation of the adhesive bond, in an embodiment of the invention, the photovoltaic modules are swiveled into a rail system of the substructure. As a result, a stable arrangement with a defined orientation of the modules relative to the substructure is achieved with little installation effort.

During the installation, the photovoltaic modules can be adhered onto the longitudinal beams of the substructure. In this context, the substructure can have a simple design since only contact surfaces for the adhesive bond are needed.

The photovoltaic array according to embodiments of the invention has at least one photovoltaic module, whereby the photovoltaic module can be affixed to a substructure. The photovoltaic module can be affixed to a stationary substructure configured as a supporting and affixing structure.

From a production engineering and installation standpoint, it may be advantageous if the photovoltaic module can be affixed directly to the substructure by means of the adhesive bond.

According to an embodiment of the invention, the substructure may have at least one longitudinal beam, whereby the photovoltaic modules can be adhered onto the longitudinal beams.

In one embodiment of the invention, the substructure is provided with at least one positioning device that serves to adjust the photovoltaic modules before and/or during the creation of the adhesive bond.

The positioning device can be temporarily disposed on the substructure. After the photovoltaic module has been installed on the substructure, the positioning device or the device that functions as a positioning aid can be removed.

The positioning device can be configured as a rail system. The side sections of the photovoltaic modules here can be gripped, at least in some sections, by projections of the rails, so that the modules are not only positioned, but also stabilized.

In a specific embodiment of the photovoltaic array, the substructure has substantially parallel rails that serve to hold the photovoltaic modules, whereby at least one longitudinal beam having a contact and adhesive surface is arranged in the center between the rails.

FIG. 1 shows a photovoltaic array 1 according to an embodiment of the invention, comprising a plurality of photovoltaic modules 2 arranged in a flat plane and affixed to a substructure 4. The photovoltaic module 2, shown by way of an example, is configured as a glass-glass laminate and affixed to the substructure 4 provided in the form of a supporting and affixing structure by means of an adhesive bond 6. In the embodiment shown, the substructure 4 is affixed to the roof 8 of a building.

It may be advantageous from a production engineering and installation standpoint for the photovoltaic module 2 to be affixed directly to the substructure 4 by means of the adhesive bond 6. In this context, the photovoltaic modules 2 are affixed directly to the substructure 4 by means of the adhesive bond 6 during the installation. As a result, there is no need for an additional stabilizing structure to be associated with the photovoltaic modules 2, so that the production engineering work is minimized and the costs are reduced.

In an embodiment the adhesive bond 6 can be created with double-faced adhesive tape 10. As a result, the modules 2 can be installed on the substructure 4 easily and quickly. In terms of production engineering, the double-faced adhesive tape 10 can be easily applied, for instance, automatically, to the bottom of the photovoltaic modules 12 while they are being produced.

In the embodiment shown, the substructure 4 is provided with a positioning device 14 that serves to adjust the photovoltaic modules 2 before and during the creation of the adhesive bond 6. The positioning device 14 is configured as an approximately T-shaped rail system 16. In the embodiment of the photovoltaic array 1 shown, the substructure 4 has parallel rails 18a, 18b that serve to hold side sections 20a, 20b of the photovoltaic modules 2, whereby a parallel longitudinal beam 22 having a contact and adhesive surface 24 is arranged in the center between the rails 18a, 18b. The side sections 20a, 20b of the photovoltaic modules 2 are gripped by projections 26 of the rails 18a, 18b, resulting in an additional stabilization of the modules 2.

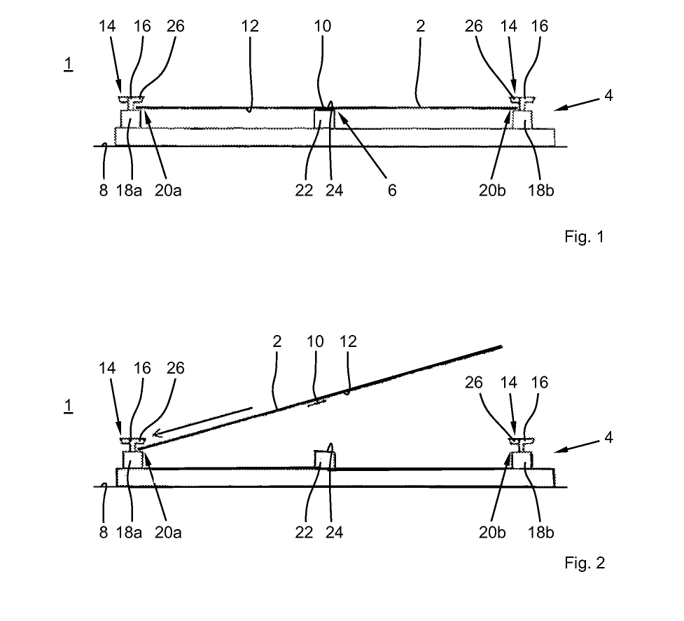

As can be seen in FIG. 2, which shows the photovoltaic array 1 before the installation of one of the photovoltaic modules 2, the photovoltaic modules 2 are swiveled (see directional arrow) into the rail system 16 of the substructure 4 in order to be positioned during the installation, that is to say, before and during the creation of the adhesive bond 6. As a result, with very little installation effort, a defined orientation of the modules 2 relative to the substructure 4 is achieved, thus making the installation easier.

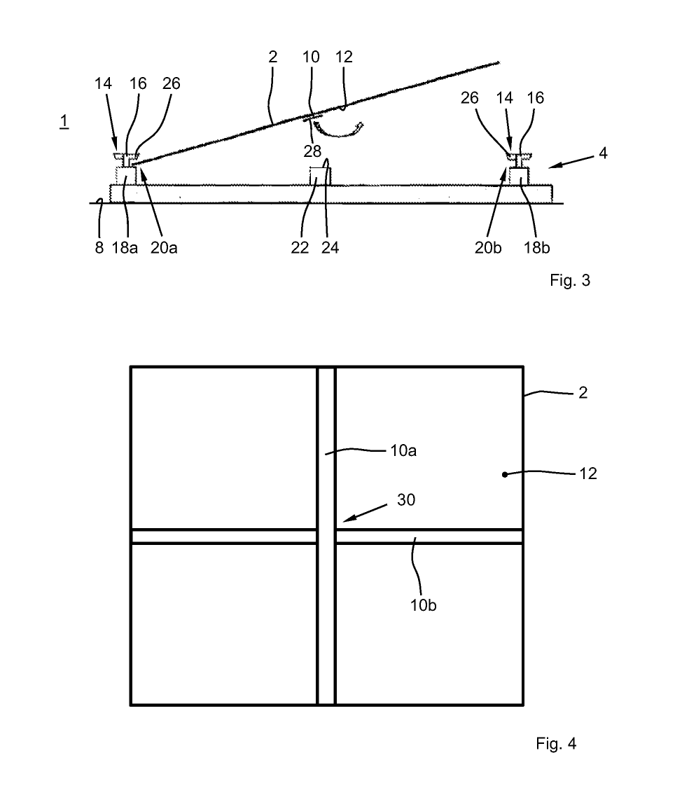

A protective peel-off backing 28 of the double-faced adhesive tape 10 is removed before or, as schematically shown in FIG. 3, after a first side section 20a of the photovoltaic modules 2 has been swiveled into place, thus exposing the adhesive surface of the double-faced adhesive tape 10 facing the longitudinal beam 22. Subsequently, the second side section 20b of the module 2 is swiveled into place, thus creating the adhesive bond 6 (see FIG. 1).

According to FIG. 4, which shows a view of the bottom 12 of a photovoltaic module 2, the double-faced adhesive tape 10 is applied as a centered strip of adhesive tape onto the bottom 12 of the photovoltaic module 2. In the embodiment shown, two strips of adhesive tape 10a, 10b are provided here that are applied in an X-shaped pattern, whereby the strip of adhesive tape 10b is in two parts, thus preventing any overlapping in the area of a center section 30. Owing to the centered strips of adhesive tape 10a, 10b, which are perpendicular to each other, the modules 2 can be installed in differently dimensioned substructures 4, irrespective of the orientation. It should be expressly pointed out that it is likewise possible to select an arrangement of the strips of adhesive tape 10a, 10b that differs from the X-shaped arrangement. The photovoltaic module 2 shown by way of an example is about 2600 mm long and about 2200 mm wide.

In an embodiment the invention provides a method for installing photovoltaic modules 2 on a substructure 4, according to which the photovoltaic modules 2 are affixed to the stationary substructure 4 configured as a supporting and affixing structure by means of an adhesive bond 6. Moreover, the invention discloses a photovoltaic array 1 having at least one photovoltaic module 2, whereby the photovoltaic module 2 can be affixed to the a stationary substructure 4 configured as a supporting and affixing structure by means of an adhesive bond 6.

While the invention has been particularly shown and described with reference to preferred embodiments thereof, it will be understood by those skilled in the art that various changes in form and details may be made therein without departing from the spirit and scope of the invention.

### LIST OF REFERENCE NUMERALS

1 photovoltaic array
2 photovoltaic module
4 substructure
6 adhesive bond
8 roof of a building
10a, b adhesive tape
12 bottom
14 positioning device
16 rail system
18a, b rail
20a, b section
22 longitudinal beam
24 contact and adhesive surface
26 projection
28 protective peel-off backing
30 center section

1. A method of installing a photovoltaic module comprising:
providing a stationary substructure configured as a supporting and affixing structure; and
affixing the photovoltaic module to the substructure by an adhesive bond.

2. The method as recited in claim 1, further comprising providing double-faced adhesive tape on at least one of the photovoltaic module and the substructure.

3. The method as recited in claim 1, wherein the substructure includes at least one longitudinal beam, and the affixing includes forming the adhesive bond on the at least one longitudinal beam.

4. The method as recited in claim 2, wherein the substructure includes at least one longitudinal beam, and the affixing includes forming the adhesive bond on the at least one longitudinal beam.

5. The method as recited in claim 1, further comprising applying double-faced adhesive tape to a bottom of the photovoltaic module during a production of the photovoltaic module.

6. The method as recited in claim 4, further comprising applying double-faced adhesive tape to a bottom of the photovoltaic module during a production of the photovoltaic module.

7. The method as recited in claim 1, wherein the substructure includes a rail system and further comprising swiveling the photovoltaic module into the rail system.

8. The method as recited in claim 2, wherein the substructure includes a rail system and further comprising swiveling the photovoltaic module into the rail system.

9. The method as recited in claim 3, wherein the substructure includes a rail system and further comprising swiveling the photovoltaic module into the rail system.

10. A photovoltaic array comprising:
a stationary substructure configured as a supporting and affixing structure; and
at least one photovoltaic module affixed to the substructure by an adhesive bond.

11. The photovoltaic array as recited in claim 10, further comprising a double-faced adhesive tape providing the adhesive bond.

12. The photovoltaic array as recited in claim 10, wherein the substructure includes at least one longitudinal beam including a contact and adhesive surface such that the at least one photovoltaic module is adhered to the at least one longitudinal beam.

13. The photovoltaic array as recited in claim 10, wherein the substructure includes a positioning device configured for adjusting the at least one photovoltaic module during a forming of the adhesive bond.

14. The photovoltaic array as recited in claim 13, wherein the positioning device is removable.

15. The photovoltaic array as recited in claim 13, wherein the positioning device is removable in sections.

16. The photovoltaic array as recited in claim 14, wherein the positioning device is configured for removal after installation of the photovoltaic module.

17. The photovoltaic array as recited in claim 15, wherein the positioning device is configured for removal after installation of the photovoltaic module.
